(19) United States
(12) Patent Application Publication
(10) Pub. No.: US 2010/0019853 A1
(43) Pub. Date: Jan. 28, 2010

(54) AMPLIFICATION STAGE

(75) Inventor: Hendrikus C. Nauta, Den Haag (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/282,240

(22) PCT Filed: Mar. 8, 2007
(86) PCT No.: PCT/IB2007/050772

§ 371 Date: Nov. 25, 2008

(30) Foreign Application Priority Data
Mar. 9, 2006 (EP) 06110918.7

(51) Int. Cl. H03F 3/68

(52) U.S. Cl. 330/310; 330/252

(57) ABSTRACT

There is provided an amplifier that comprises a plurality of amplifier stages arranged in a cascade; and a frequency-dependent load associated with the output of at least one of the plurality of amplifier stages, the frequency dependent load being adapted to reduce a voltage or current offset in the output of said at least one amplifier stage.

### TECHNICAL FIELD OF THE INVENTION

The invention relates to an amplification stage, and in particular to an amplification stage for a radio receiver which allows signal strength measurements to be made of received signals.

### BACKGROUND TO THE INVENTION

In a wireless radio receiver, an incoming high-frequency radio signal, such as an FM radio signal, is converted into a signal with an intermediate frequency (IF), which is then amplified and passed to a demodulator which retrieves information, such as baseband audio, from the radio signal. Often, the radio needs received signal strength information (RSSI) as part of the receiver's tuning algorithm (like search tuning). On the other hand, the demodulator might require this RSSI information as well, in order to successfully retrieve the baseband information.

Assuming that the demodulator does not need to add any additional channel selectivity to the receiver, the information in a frequency modulated (FM) signal is solely present in the phase (or “zero-crossings”) of the IF signal. Therefore, a hard-limiting IF amplifier can be used to amplify the signal from the IF filter. The gain of the IF amplifier will usually be in the range of 50-90 dB, depending on the specific receiver architecture.

With such high gains, any dc-offset introduced in the amplification may result in undesired asymmetrical limiting or, worse, a complete blocking of amplification of weak IF input signals.

In an integrated circuit (IC) process, offset voltages and currents are introduced due to matching errors of the various components and thus offsets are inherently present in all circuits.

The IF amplifier and limiter usually consists of a cascade of individual limiting amplifier stages. Each limiting amplifier allows signals below a set value to pass, and clips the peaks of stronger signals that exceed this set value. In such a cascade, it is known to output RSSI information from each of the amplifier stages and to sum the individual measurements to arrive at a final value. Thus, any dc-offset present in each individual amplifier stage will affect the accuracy of the measured RSSI signal.

This type of IF limiter and amplifier is described in US 2006/046677.

One way of reducing or preventing the undesired transfer of dc-offset voltages and currents into the RSSI signal is to use coupling capacitors between some of the amplifier stages, or to apply a low-frequency feedback loop around several limiting amplifier stages.

In these solutions, the coupling capacitors tend to have relatively large values to keep the low-frequency noise at an adequately low level, as well as to keep the group-delay ripple within acceptable limits. The group-delay ripple is a dominant parameter with respect to the detected audio distortion. For the same reasons, the resistors and capacitors in a low-frequency feedback loop also tend to have large values.

Unfortunately, the large-valued components use an undesirably large chip area and provide undesired parasitic effects. For this reason, there is a trade-off between RSSI accuracy and group-delay distortion and consumed chip area, which is not easy to resolve and tends to result in either a rather large RSSI error or an inferior group-delay and noise performance.

Therefore, it is an object of the invention to reduce the dc-offset in the limiting amplifier stages in order to avoid or reduce the need for coupling capacitors or a low-frequency feedback loop.

### SUMMARY OF THE INVENTION

In accordance with a first aspect of the invention, there is provided an amplifier, comprising a plurality of amplifier stages arranged in a cascade; and a frequency-dependent load associated with the output of at least one of the plurality of amplifier stages, the frequency dependent load being adapted to reduce a voltage or current offset in the output of said at least one amplifier stage. This results in the dc offset being reduced at the output of the at least one amplifier stage.

Preferably, there is a frequency dependent load associated with the output of each of the plurality of amplifier stages. This allows the dc offset to be reduced at the output of each amplifier stage.

Preferably, the frequency dependent load comprises a load amplifier.

Preferably, the load amplifier comprises a two-stage feedback amplifier.

In a preferred embodiment, the frequency dependent load is adapted to reduce noise at frequencies below an intermediate frequency.

Preferably, the amplification of the associated amplifier stage is less than 1 for frequencies below the intermediate frequency.

Preferably, the amplification of the associated amplifier stage is much less than 1 for frequencies below the intermediate frequency.

Preferably, the frequency dependent load is further adapted to pass signals at the intermediate frequency substantially unchanged.

Preferably, the amplifier further includes a respective received signal strength indication detection circuit connected to the output of each of the plurality of amplifier stages. Preferably, there is a summing circuit for receiving the outputs of each of said detection circuits and for adding the outputs to provide a received signal strength indication.

In accordance with a second aspect of the invention, there is provided a silicon integrated radio receiver comprising an amplifier as described above.

These and other aspects of the invention will be apparent from and elucidated with reference to the embodiments described hereinafter.

### BRIEF DESCRIPTION OF THE DRAWINGS

The invention will now be described, by way of example only, with reference to the following drawings, in which:

FIG. 1 shows a block schematic of an IF amplifier in accordance with the invention;

FIG. 2 shows a block diagram of a frequency dependent load in accordance with the invention;

FIG. 3 shows an equivalent circuit of an ideal frequency dependent load in accordance with the invention;

FIG. 4 is a circuit diagram of an amplifier stage, a frequency dependent load and an RSSI detection circuit in accordance with an embodiment of the invention; and

FIG. 5 is a circuit diagram of a first amplifier stage and frequency dependent load in an amplifier in accordance with an embodiment of the invention.

### DETAILED DESCRIPTION OF THE PREFERRED EMBODIMENTS

In the following, an IF amplifier will be described for use in a silicon-integrated FM radio receiver. However, it will be appreciated by a person skilled in the art that the invention can be applied to other types of radio receiver.

FIG. 1 shows a block schematic of an IF amplifier 2 in accordance with the invention. As described above, the amplifier 2 comprises a cascade 4 of limiting amplifier stages. The limiting amplifier stages are arranged in a cascade. A first limiting amplifier stage 6 and a second limiting amplifier stage 8 are shown in the cascade 4, with the stages 6, 8 being connected in cascade. Although only two stages are illustrated in the cascade 4 shown in FIG. 1, it will be appreciated that it is possible to use many more than two stages in a practical IF amplifier 2.

The first limiting amplifier stage 6 of the cascade 4 receives an IF signal at IF signal input 10 which it amplifies and passes to the second limiting amplifier stage 8, and so on, until the amplified signal is output from the IF amplifier 2 at IF signal output 12.

In accordance with one aspect of the invention, instead of outputting a received signal strength indicator (RSSI) directly from a or each limiting amplifier stage, respective received signal strength indicator (RSSI) detectors 14, 16 are connected to the outputs 60, 80 of each limiting amplifier stage 6, 8 in the cascade 4. The RSSI detectors 14, 16 extract RSSI information from the outputs 60, 80 of their respective limiting amplifier stages 6, 8. The RSSI information is passed by each RSSI detector 14, 16 to a summing block 18, which adds the detected signal levels together. The summing block 18 then provides a received signal strength indication signal on output 20.

As mentioned above, offset voltages and currents will be introduced in the IF amplifier 2 as a result of matching errors of the various components used in the limiting amplifier stages 6, 8. Thus, it is desirable to reduce this offset in the limiting amplifier stages in order to avoid or reduce the need for coupling capacitors or a low-frequency feedback loop.

Therefore, in accordance with the invention, a frequency dependent load is provided for at least one of the limiting amplifier stages 6, 8 to reduce the voltage and/or current offset. In a preferred embodiment of the invention, the frequency dependent load operates such that the amplification of signals at zero and low frequencies by the associated limiting amplifier stage is less than 1, while the amplification of signals at intermediate frequencies is substantially unaffected. In other words, the signals at intermediate frequencies are normally amplified by the respective limiting amplifier stage. In a further preferred embodiment of the invention, the frequency dependent load operates such that the amplification of signals at zero and low frequencies by the associated limiting amplifier stage is much less than 1.

In a further preferred embodiment of the invention, and as illustrated in FIG. 1, each of the limiting amplifier stages 6, 8 in the IF amplifier 2 has a respective frequency dependent load 22, 24 connected to their respective outputs 60, 80.

In its basic (ideal) form, the frequency-dependent load is modelled by a passive L, R and C circuit. However, this model is realised in practice (i.e. on chip) through the use of a feedback amplifier, which will be referred to herein as a “load amplifier”. These load amplifiers have to operate as pure linear amplifiers under all signal levels to adequately implement the L, R and C model.

In a preferred embodiment of the invention, the load amplifier is implemented as a two-stage feedback amplifier. In this embodiment, the resulting load characteristics can be designed such that they have a negligible effect on the group-delay and can be realised with small capacitor values, thereby reducing the on-chip area used.

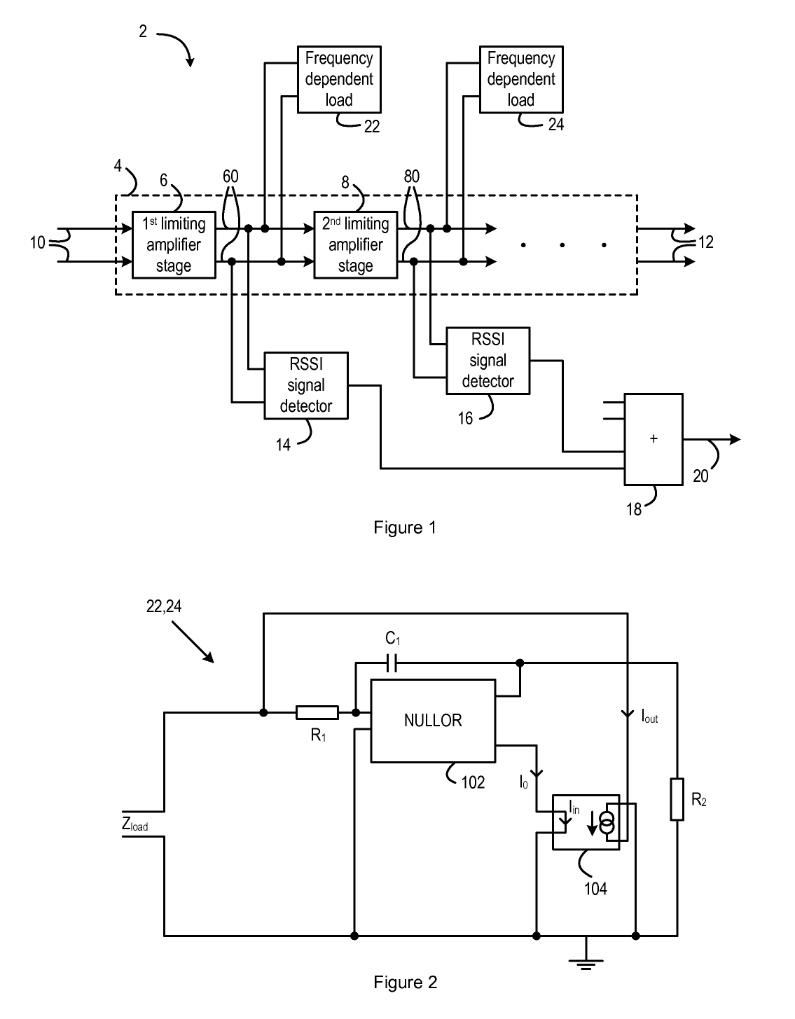

FIG. 2 is a block diagram of a load amplifier 22, 24 in accordance with the invention that comprises a two-stage feedback amplifier.

In this Figure, the nullor block 102 represents a network element having all four transmission parameters equal to zero. The inverse of these transmission parameters are the well-known parameters, voltage-gain factor, current-gain factor, transadmittance and transimpedance. For the ideal nullor, all these inverse transmission parameters are infinity.

The block 104 represents an amplifier with an accurately fixed current-gain factor β_{E} with a value of −1/m, where m is a constant value, and is preferably in the range from 1 to 10. Block 104 forces the output current Iₒᵤₜ to be equal to Iₒ/m, where Iₒ represents the current flowing in the output port of nullor 102.

Solving an equation associated with the structure in FIG. 2 results in the following expression for the input impedance.

The load input impedance, Z_{load}, of the load amplifier in FIG. 2 is given by the equation

$${Z}_{load} = \frac{{pL}_{p}}{{pL}_{p} + {R}_{p}} \qquad ( 1 )$$

where Lₚ and Rₚ are given by:

$${L}_{p} = {mR}_{1} {R}_{2} {C}_{1} ; and {R}_{p} = \frac{m}{m + 1} {R}_{1} \qquad ( 2 )$$

Thus, the frequency response characteristics of the illustrated implementation of the load amplifier 22, 24 result in the low frequency noise in the received IF signal being adequately filtered while DC offsets are totally suppressed, with the noise level at the desired IF frequency being substantially unchanged by the load amplifier.

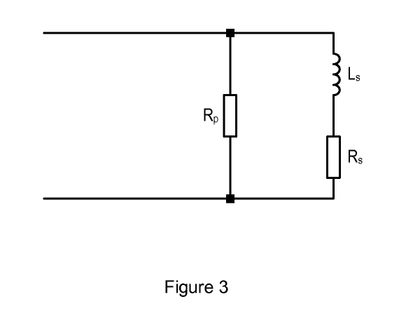

These equations indicate that the load impedance of the load amplifiers are equivalent to the ideal circuit depicted in FIG. 3.

FIG. 3 shows an L-R equivalent circuit of an ideal frequency dependent load in accordance with the invention. The circuit comprises an inductor with value Lₛ connected in series with a resistor with value Rₛ, with both of these elements being connected in parallel to a second resistor Rₚ. In the ideal case, Rₛ will be zero. Thus, by connecting the equivalent load circuit as depicted in FIG. 3 to the outputs of each of the limiting amplifier stages 6, 8 in the cascade 4, the DC offset at each of these outputs will be effectively removed by the inductor Lₛ.

However, in a practical transistor implementation of the frequency dependent load, the equivalent series resistor Rₛ will not be zero, and consequently there will only be a finite suppression of DC offset voltages (i.e. the DC offset will not be totally removed by the frequency dependent load).

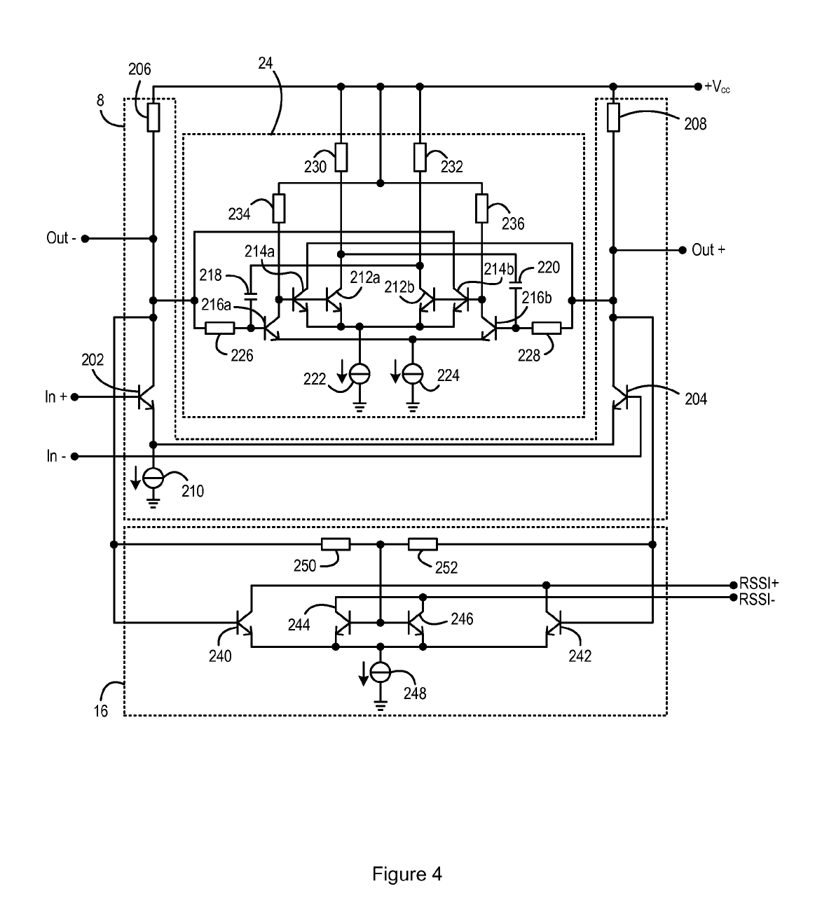

FIG. 4 is a circuit diagram showing a preferred implementation of a limiting amplifier stage, associated frequency dependent load and RSSI detection circuit in accordance with an embodiment of the invention.

Although a particular circuit layout is shown, it will be appreciated by a person skilled in the art that the invention can be implemented using alternative circuit components and/or a different circuit layout.

In FIG. 4, the second limiting amplifier stage 8 is shown (which is the second amplifier stage in a cascade of limiting amplifier stages), with associated RSSI signal detection circuit 16 and frequency dependent load 24. However, it will be appreciated that FIG. 4 can represent any of the other stages in the IF amplifier 2 shown in FIG. 1.

The second limiting amplifier stage 8 comprises a pair of transistors 202, 204 arranged as a differential pair. Thus, the transistors 202, 204 have respective resistors 206, 208 connected between voltage supply +V_{cc} and their collector terminals. The input signals to the limiting amplifier 8, In+ and In− are connected to the base terminals of the transistors 202, 204 respectively. The output signals of the limiting amplifier 8, Out+ and Out− are connected between the collector terminals of the transistors 202, 204 and the respective resistors 206, 208. The emitter terminals of the transistors 202, 204 are connected to a current source 210.

In accordance with the invention, a frequency dependent load, in this case a load amplifier 24, is connected to the second limiting amplifier stage 8, in order to reduce the dc offset in the output of the limiting amplifier 8.

This load amplifier 24 is a circuit implementation of the frequency dependent load shown in FIG. 2. The load amplifier 24 has three differential pairs, including transistor 212a paired with transistor 212b, transistor 214a paired with transistor 214b and transistor 216a paired with transistor 216b. The collector currents of transistors 214a and 214b are scaled copies of the collector currents of transistors 212a and 212b. These currents are scaled by a factor m, which represents the current-gain factor β_{E}=m of the block 104 in FIG. 2. A capacitor 218 is connected between the collector and base terminals of transistors 212b and 216a respectively. Likewise, a capacitor 220 is connected between the collector and base terminals of transistors 212a and 216b respectively.

The emitter terminals of transistors 212a, 212b, 214a and 214b are connected to a current source 222. The emitter terminals of transistors 216a and 216b are connected to a current source 224.

The collector terminals of transistors 214a and 214b are connected to the outputs of the limiting amplifier 8, Out+ and Out− respectively. The base terminals of transistors 216a and 216b are also connected to the outputs (Out− and Out+ respectively) of the limiting amplifier 8 via respective resistors 226 and 228.

The collector terminals of transistors 212a and 212b are connected to voltage supply +V_{cc} via respective resistors 230 and 232. The collector terminal of transistor 216a is connected to the base terminals of transistors 212a and 214a and to voltage supply +V_{cc} via resistor 234. The collector terminal of transistor 216b is connected to the base terminals of transistors 212b and 214b and to voltage supply +V_{cc} via resistor 236.

Instead of using the differential pairs in the limiting amplifier stage 8 to extract the RSSI information, the RSSI detection circuit 16 is used to extract the RSSI information from the output of the limiting amplifier stage 8.

The RSSI detection circuit 16 comprises transistors 240, 242, 244 and 246. The emitter terminals of each of the transistors is connected to a current source 248. A voltage divider comprising resistors 250 and 252 is connected between the outputs, Out+ and Out−, of the limiting amplifier stage 8. The output of the voltage divider is connected to the base terminals of transistors 244 and 246.

The base terminals of transistors 240 and 242 are connected to the outputs Out− and Out+ of the limiting amplifier 8 respectively. The collector terminals of transistors 240 and 242 provide the RSSI signal out, RSSI+, and the collector terminals of transistors 244 and 246 provide the RSSI signal out, RSSI−.

It will be appreciated that as the voltage and/or current offset is removed at the output 60, 80 of each limiting amplifier stage 6, 8 by their respective frequency dependent loads 22, 24, there is a special situation at the input to the first limiting amplifier stage 6.

The offset present at the input of the first limiting amplifier stage 6 must be linearly amplified to its output 60, in order for the frequency dependent load 22 (load amplifier) to adequately remove the offset without affecting the IF signal response. Therefore, the first limiting amplifier stage 6 preferably has a larger linear input range than the other limiting amplifier stages.

In a preferred embodiment, the first limiting amplifier stage 6 comprises a three-stage multitan circuit which can linearly handle input offset voltages up to 50 mV, and in which the resulting offset at the output of this input amplifier can adequately be removed.

The other limiting amplifier stages do not require an extended linear input range, as the offset at the input of these stages is adequately reduced by the frequency-dependent load.

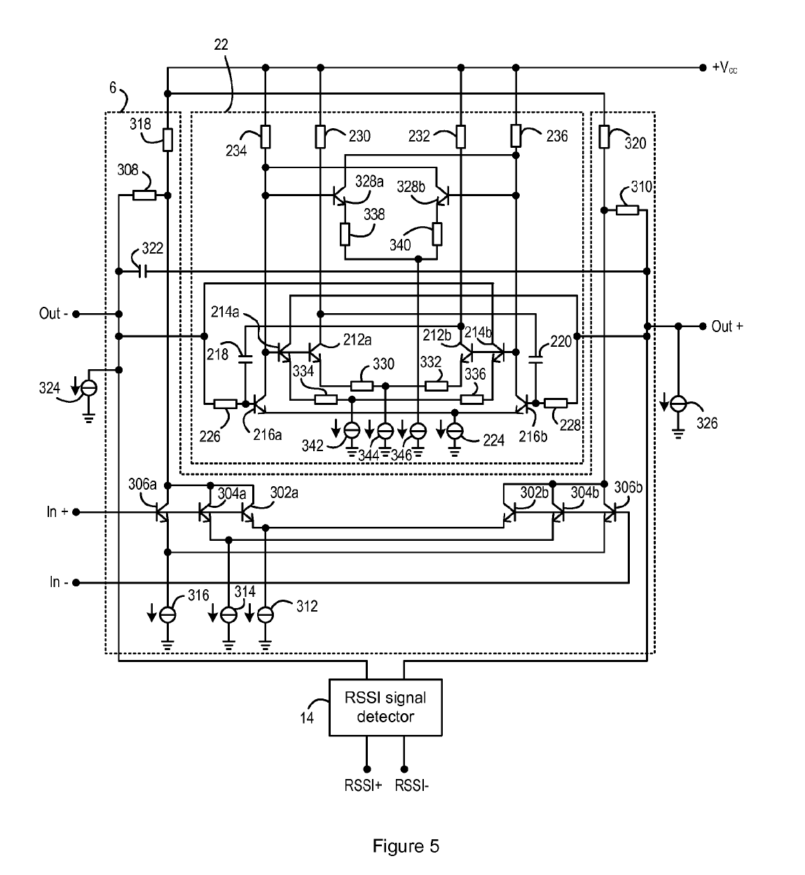

FIG. 5 is a circuit diagram of a limiting amplifier stage having an extended linear input range and frequency dependent load in an amplifier in accordance with an embodiment of the invention.

Again, although a particular circuit layout is shown, it will be appreciated by a person skilled in the art that the invention can be implemented using alternative circuit components and/or a different circuit layout.

In FIG. 5, the first limiting amplifier stage 6 is shown, with associated RSSI signal detection circuit 14 and frequency dependent load in the form of a load amplifier 22.

As mentioned above, in this embodiment, the limiting amplifier 6 is realized by multitan differential stages. The limiting amplifier 6 comprises three differential transistor pairs, transistors 302a and 302b form the first pair, transistors 304a and 304b form the second pair, and transistors 306a and 306b form the third pair. Input signal In+ is provided to the base terminals of transistors 302a, 304a and 306a, and input signal In− is provided to the base terminals of transistors 302b, 304b and 306b.

Amplifier stage 6 has a more linear transfer from an input voltage received on input lines In+ and In− to the signal output on lines Out− and Out+ (via respective resistors 308, 310) in comparison to the single differential pair in the second limiting amplifier stage 8 described above. For this reason, larger input signals can be handled, which therefore increases the dynamic range of the amplifier 6. Transistors 304a and 306b occupy seven times the area of the other transistors 302a, 302b, 304b and 306a. The tail currents 316 and 314 have two times the value of the tail current 312. This area ratio and tail-current ratio results into the best linear transfer from input voltage to output current.

The emitters of the transistors 302a and 302b of the first differential pair are connected to a current source 312. The emitter of the transistors 304a and 304b of the second differential pair are connected to a current source 314. The emitter of the transistors 306a and 306b of the third differential pair are connected to ground via a current source 316.

The collector terminals of the transistors 302a, 304a and 306a and 302b, 304b and 306b are connected between to the voltage supply +V_{cc} via respective resistors 318, 320.

A capacitor 322 is connected between the outputs, Out+ and Out−. The outputs Out− and Out+ are connected to respective current sources 324 and 326.

The load amplifier 22 is a circuit implementation of the frequency dependent load shown in FIG. 2. Elements in the load amplifier 24 of FIG. 4 that correspond to elements in the load amplifier 22 described below are given the same reference numerals. The load amplifier 22 has four differential pairs, including transistor 212a paired with transistor 212b, transistor 214a paired with transistor 214b, transistor 216a paired with transistor 216b and transistor 328a paired with transistor 328b. A capacitor 218 is connected between the collector and base terminals of transistors 212b and 216a respectively. Likewise, a capacitor 220 is connected between the collector and base terminals of transistors 212a and 216b respectively.

The emitter terminals of transistors 212a and 212b, 214a and 214b, and 328a and 328b are connected together through respective voltage dividers comprising resistors 330, 332; 334, 336; and 338, 340 respectively. The outputs of the voltage dividers are connected to respective current sources 342, 344 and 346. The emitter terminals of transistors 216a and 216b are connected to current source 224.

The collector terminals of transistors 214a and 214b are connected to the outputs of the limiting amplifier 6, Out+ and Out− respectively. The base terminals of transistors 216a and 216b are also connected to the outputs (Out− and Out+ respectively) of the limiting amplifier 8 via respective resistors 226 and 228.

The collector terminals of transistors 212a and 212b are connected to voltage supply +V_{cc} via respective resistors 230 and 232. The collector terminal of transistor 216a is connected to the base terminals of transistors 212a, 214a and 328a and to voltage supply +V_{cc} via resistor 234. The collector terminal of transistor 216b is connected to the base terminals of transistors 212b, 214b and 328b and to voltage supply +V_{cc} via resistor 236.

The collector terminal of transistor 328a is connected to the collector of transistor 216b and the collector terminal of transistor 328b is connected to the collector of transistor 216a.

Again, instead of using the differential pairs in the limiting amplifier stage 6 to extract the RSSI information, the RSSI detection circuit 14 is used to extract the RSSI information from the output of the limiting amplifier stage 6. The RSSI detector circuit 14 is connected between the outputs of the limiting amplifier 6, Out+ and Out−, and corresponds to the circuit 16 shown in FIG. 4.

While the invention has been illustrated and described in detail in the drawings and foregoing description, such illustration and description are to be considered illustrative or exemplary and not restrictive; the invention is not limited to the disclosed embodiments. For example, although the invention has been described as an IF amplifier for use in a silicon-integrated FM radio receiver, the invention can be applied to other types of radio receiver that include a cascade of limiting amplifiers in the signal path (although usually in the IF signal path of the receiver) with or without RSSI extraction.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

1. An amplifier, comprising:
a plurality of amplifier stages arranged in a cascade; and
a frequency-dependent load associated with the output of at least one of the plurality of amplifier stages, the frequency dependent load being adapted to reduce a voltage or current offset in the output of said at least one amplifier stage.

2. An amplifier as claimed in claim 1, wherein there is a frequency dependent load associated with the output of each of said plurality of amplifier stages.

3. An amplifier as claimed in claim 1, wherein the frequency dependent load comprises a load amplifier.

4. An amplifier as claimed in claim 3, wherein the load amplifier comprises a two-stage feedback amplifier.

5. An amplifier as claimed in claim 1, wherein the frequency dependent load is adapted to reduce noise at frequencies below an intermediate frequency.

6. An amplifier as claimed in claim 5, wherein the amplification of the associated amplifier stage is less than 1 for frequencies below the intermediate frequency.

7. An amplifier as claimed in claim 6, wherein the amplification of the associated amplifier stage is much less than 1 for frequencies below the intermediate frequency.

8. An amplifier as claimed in claim 5, wherein the frequency dependent load is further adapted to pass signals at the intermediate frequency substantially unchanged.

9. An amplifier as claimed in claim 1, further comprising a respective received signal strength indication detection circuit connected to the output of each of said plurality of amplifier stages.

10. An amplifier as claimed in claim 9, further comprising a summing circuit for receiving the outputs of each of said detection circuits and for adding the outputs to provide a received signal strength indication.

11. A silicon integrated radio receiver comprising an amplifier as claimed in any preceding claim.

12. A silicon integrated radio receiver as claimed in claim 11, wherein the radio receiver is for receiving FM radio signals.
